(19) United States
(12) Patent Application Publication
(10) Pub. No.: US 2011/0074459 A1
(43) Pub. Date: Mar. 31, 2011

(54) STRUCTURE AND METHOD FOR SEMICONDUCTOR TESTING

(75) Inventors: Wei Wei Ruan, Shanghai (CN); Bin Gong, Shanghai (CN); Wen Shi, Shanghai (CN)

(73) Assignee: Semiconductor Manufacturing International (Shanghai) Corporation, Shanghai (CN)

(21) Appl. No.: 12/887,491

(22) Filed: Sep. 21, 2010

(30) Foreign Application Priority Data
Sep. 28, 2009 (CN) 200910057966.8

(51) Int. Cl. G01R 31/26; H01L 23/48

(52) U.S. Cl. 324/762.01; 257/48; 257/E23.01

(57) ABSTRACT

An embodiment of a test structure in accordance with the present invention comprises a pair of interdigitated comb portions of a metallization layer present in a recess of an inter-layer dielectric (ILD) formed over a polysilicon heater element. A third portion of the metallization layer comprises a serpentine metal line interposed between the comb portions. Application of force voltages, and detection of sense voltages, at various nodes of the metallization portions allows identification of the following: (1) electromigration of metal in the metallization portions; (2) extrusion of metal from one metallization portion to contact another; (3) breakdown voltage (V_{bd}) and time dependent dielectric breakdown (TDDB) of the ILD; (4) contamination in the metallization portions with mobile ions; and (5) k valve and drift in k value of the ILD. A bias voltage may be applied to the polysilicon heater to accomplish temperature control during testing.

### CROSS-REFERENCES TO RELATED APPLICATIONS

This application claims priority to Chinese Patent Application No. 200910057966.8, filed on Sep. 28, 2009, by inventors Wei Wei Ruan et al., commonly assigned and incorporated in its entirety by reference herein for all purposes.

### BACKGROUND OF THE INVENTION

The present invention is directed to integrated circuits and their processing for the manufacture of semiconductor devices. In particular, the invention provides a method and system for testing the interconnect structures. More particularly, the invention provides a method and device for testing a plurality of electronic attributes of a copper interconnect structure, but it would be recognized that the invention has a much broader range of applicability.

Integrated circuits have evolved from a handful of interconnected devices fabricated on a single chip of silicon to millions of devices. Conventional integrated circuits provide performance and complexity far beyond what was originally imagined. In order to achieve improvements in complexity and circuit density (i.e., the number of devices capable of being packed onto a given chip area), the size of the smallest device feature, also known as the device “geometry”, has become smaller with each generation of integrated circuits.

Increasing circuit density has not only improved the complexity and performance of integrated circuits but has also provided lower cost parts to the consumer. An integrated circuit or chip fabrication facility can cost hundreds of millions, or even billions, of U.S. dollars. Each fabrication facility will have a certain throughput of wafers, and each wafer will have a certain number of integrated circuits on it. Therefore, by making the individual devices of an integrated circuit smaller, more devices may be fabricated on each wafer, thus increasing the output of the fabrication facility. Making devices smaller is very challenging, as each process used in integrated fabrication has a limit. That is to say, a given process typically only works down to a certain feature size, and then either the process or the device layout needs to be changed. Additionally, as devices require faster and faster designs, process including testing limitations exist with certain conventional processes and testing procedures for wafer reliability.

As merely an example, aluminum metal layers have been the choice of material for semiconductor devices as long as such layers have been used in the first integrated circuit device. Aluminum had been the choice since it provides good conductivity and sticks to dielectric materials as well as semiconductor materials.

Most recently, aluminum metal layers have been replaced, in part, by copper interconnects. Copper interconnects have been used with low k dielectric materials to form advanced conventional semiconductor devices. Copper has improved resistance values of aluminum for propagating signals through the copper interconnect at high speeds.

As devices become smaller and demands for integration become greater, limitations in copper and low k dielectric materials include unwanted migration of Cu or other conducting materials into other portions of the integrated circuit. Accordingly, conducting copper features are typically encased within barrier materials such as silicon nitride (SiN), which impede the diffusion of the copper.

Cu dislocation at post-CMP copper surface and SiN cap is one of top killer mechanisms affecting copper backend reliability failures as well as electric failures. One example of such a failure is local bridging of two or multiple metal lines by high temperature operating life (HTOL) stress.

Examples of Cu dislocation triggered by electromigration include copper mass migration, void formation during grain growth, and grain boundary reorganization. Controlling Cu dislocation is a key solution to improve reliability and yield issues due to such related fail modes.

FIG. 1A shows simplified cross-sectional view of a copper feature 2 formed within dielectric 4 and sealed by overlying silicon nitride barrier layer 6. FIG. 1A shows that the presence of topography such as hillocks 8 and voids 10 in the copper, can produce uneven thickness and passivation in the overlying SiN barrier layer. As a result, upon exposure of the copper-containing structure to the flow of charge, stress release along grain boundaries of the copper can result in unwanted migration, breaking the SiN barrier.

FIG. 1B is an electron micrograph showing a cross section of metal bridging after stress due to copper dislocation. FIG. 1B shows the electrically stressed metal lines fabricated without copper dislocation control, where bulk copper migration outside of trench is seen. This migration caused an electric short and destroyed the functionality of the die.

The sudden and catastrophic failure of the device of FIG. 1A is to be avoided. Accordingly, engineers have developed tests for estimating the amount of migration expected to occur in a device experiencing the application of a potential difference. These tests involve the application of voltage to test structures on the surface of the chip. These test structures are not intended to operate during actual functioning of the chip, but rather are present solely to allow the application of voltage to access the amount of unwanted migration that is expected to occur.

Conventionally, separate test structures have been required to identify electromigration that are used for other testing purposes such as identifying absolute voltage breakdown (V_{bd}) or time dependent dielectric breakdown (TDDB). Such multiple conventional test structures occupy valuable real estate on the chip that is more profitably allocated to active devices.

From the above, it is seen that improved techniques and structures for testing semiconductor devices are desired.

### BRIEF SUMMARY OF THE INVENTION

An embodiment of a test structure in accordance with the present invention comprises a first portion and a second portion of a metallization layer, wherein the first and second portions have the shape of a comb and are formed in a recess of an inter-layer dielectric (ILD) formed over a polysilicon heater element and patterned in an interdigitated comb structure. A third portion of the metallization layer comprises a serpentine metal line interposed between the first and second comb portions. Application of force voltages, and detection of sense voltages, at various nodes of the metallization portions allows identification of the following: (1) electromigration of metal in the metallization portions; (2) extrusion of metal from one metallization portion to contact another; (3) breakdown voltage (V_{bd}) and time dependent dielectric breakdown (TDDB) of the ILD; (4) contamination in the metallization portions with mobile ions; and (5) k valve and drift in k value of the ILD. A bias voltage may be applied to the polysilicon heater to accomplish temperature control during testing.

An embodiment of a test structure, in accordance with the present invention, comprises a polysilicon pad formed on a substrate and a dielectric layer formed on the polysilicon pad. A metallization layer is formed in a recess in the dielectric layer, the metallization layer comprising a first comb portion interdigitated with and electrically isolated from a second comb portion by the dielectric layer.

An embodiment of a method in accordance with the present invention for testing a semiconductor substrate, comprises, providing a test structure comprising a polysilicon pad formed on a substrate, a dielectric layer formed on the polysilicon pad, and a metallization layer formed in a recess in the dielectric layer, the metallization layer comprising a first comb portion interdigitated with a second comb portion and electrically isolated from the second comb portion by the dielectric layer. A voltage is then applied to the first comb portion.

Various additional objects, features and advantages of the present invention can be more fully appreciated with reference to the detailed description and accompanying drawings that follow.

### BRIEF DESCRIPTION OF THE DRAWINGS

FIG. 1A is a simplified cross-sectional view of a copper structure experiencing unwanted copper migration in response to a thermal cycle.

FIG. 1B is an electron micrograph showing a cross section of metal bridging after stress due to copper dislocation.

FIG. 2 shows a simplified plan view of a conventional structure for testing leakage between adjacent portions of a copper interconnect layer.

FIG. 3 shows a simplified plan view of an embodiment of a test structure in accordance with the present invention.

### DETAILED DESCRIPTION OF THE INVENTION

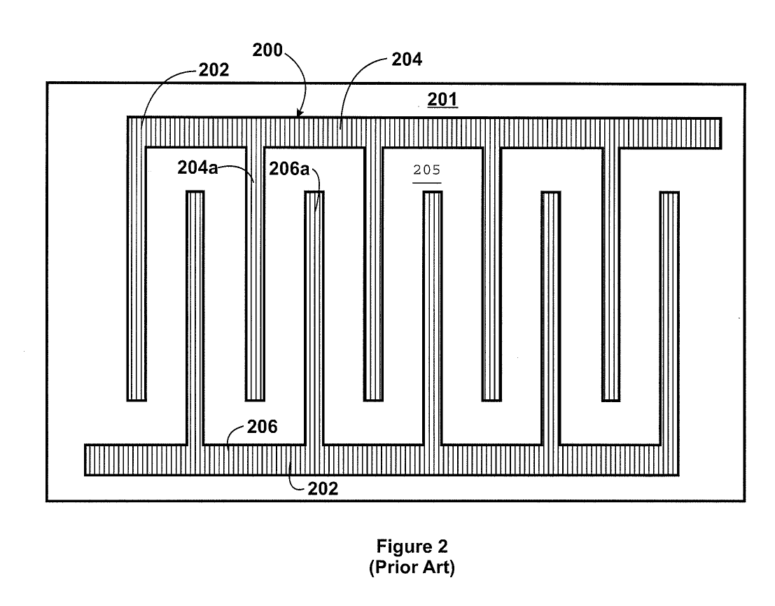

FIG. 2 shows a simplified plan view of a conventional structure for testing leakage between adjacent portions of a copper interconnect layer. Specifically, conventional test structure 200 comprises a copper metallization layer 202 formed within a dielectric layer 205. Copper metallization layer 202 has been patterned into separate portions 204 and 206, typically utilizing a Damascene process. Copper portions 204 and 206 have the shape of a comb, with adjacent projecting portions 204a and 206a oriented substantially parallel to one another. Test structure 200 is formed on an underlying substrate 201.

The test structure of FIG. 2 is conventionally used to test for leakage between the adjacent comb portions. For example, detection of a sense voltage on first metallization line 204 in the presence of a force voltage on second metallization line 206, would reveal leakage between the metallization lines. Such leakage could be attributable, for example, to unwanted extrusions or bridges between the portions of the Cu layer. Such extrusions or bridges could remain after completion of the damascene process, or could be formed afterward by electromigration of the Cu layer under applied currents or thermal energies.

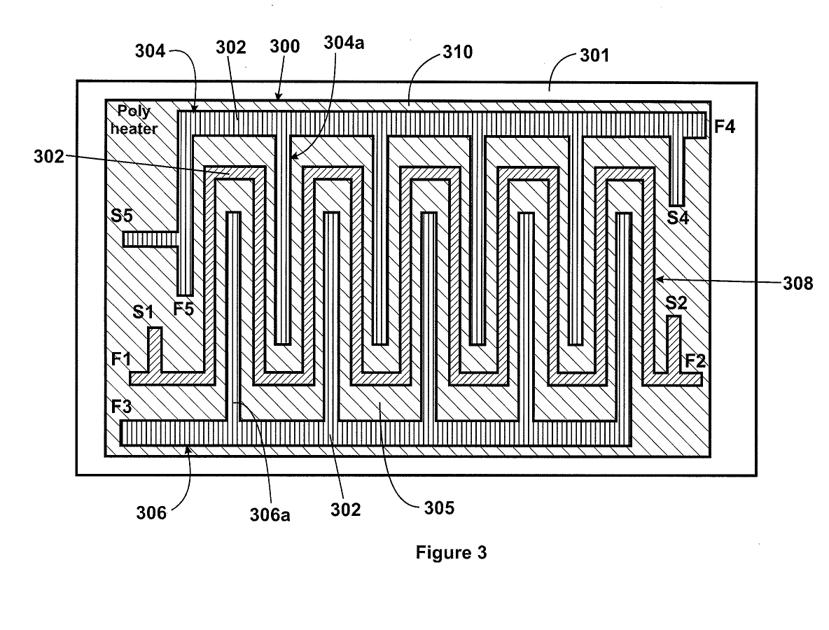

While the conventional test structure of FIG. 2 is capable of detecting leakage between adjacent portions of a metallization layer, this structure is not typically employed to test other attributes of the copper metallization layer. Accordingly, FIG. 3 shows a simplified plan view of one embodiment of a test structure of the present invention.

Like the conventional test structure of FIG. 2, test structure 300 comprises a copper metallization layer 302 formed within a recess in a dielectric layer 305. Unlike the conventional test structure shown in FIG. 2, however, copper metallization layer 302 has been patterned into three separate portions 304, 306, and 308. Patterning of the metallization layer is typically achieved utilizing a Damascene process in which copper is formed by electroplating within the recess etched in the dielectric layer. The electroplated copper is subsequently removed outside of the recess by chemical mechanical polishing (CMP) techniques.

Copper portions 304 and 306 have the shape of a comb, with adjacent projecting portions 304a and 306a oriented substantially parallel to one another. A first end of copper portion 304 includes a sense node S5 and a force node F5. A second end of copper portion 304 includes a sense node S4 and force node F4. A first end of copper portion 306 includes a force node F3.

Third portion 308 of copper metallization layer 302 is formed in a serpentine shape between portions 304 and 306, and in particular between parallel portions 304a and 306a. A first end of third portion 308 includes a force node F1 and a sense node S1. A second end of third portion 308 includes a force node F2 and a sense node S2.

Also unlike the conventional test structure of FIG. 2, the embodiment of the test structure in accordance with the present invention shown in FIG. 3 includes a polysilicon pad 310 lying between substrate 301 and the metallization layer 302. Application of electrical bias to polysilicon pad 310 results in heating thereof. Thus, inclusion of polysilicon pad 310 in the test structure 300 allows for precise control over the temperature of the test structure.

The test structure 300 of FIG. 3 may be operated in a number of different ways to identify various characteristics of the copper metallization layer. For example, in a first operational mode, test structure 300 may be employed to test for electromigration (EM) within one or more of the portions of the copper metallization layer.

Specifically, incorporated herein by reference for all purposes are the following document: EIA/JEDEC Standard EIA/JESD61 (April 1997), entitled “Isothermal Electromigration Test Procedure”. This document describes a standardized test for evaluating electromigration (EM) along the lines of metallization components of interconnect structures. In particular, this test is used to identify electromigration occurring along relatively long metal lines, for example pieces of metallization having a length of 200 m or greater, and typically 800 m or greater. This EM test is performed by applying a force voltage at a force node of a test structure to induce the electromigration, and receiving at a sense node a sense voltage revealing a changed electrical resistance resulting from electromigration of the metal material.

Accordingly, the test structure 300 of FIG. 3 may be utilized to identify electromigration as follows. First, a force voltage is applied to one of force nodes F1, F2, F4, and F5 found on one of the interconnect metallization lines 304 or 308. A sense voltage is then sensed at the corresponding sense node present on the other end of that line of metallization (S2, S1, S5, or S4, respectively). Where the force voltage is maintained constant over time, a change in the sense voltage reveals a change in resistance of the interconnect metallization, and thus the existence of electromigration within the interconnect metallization.

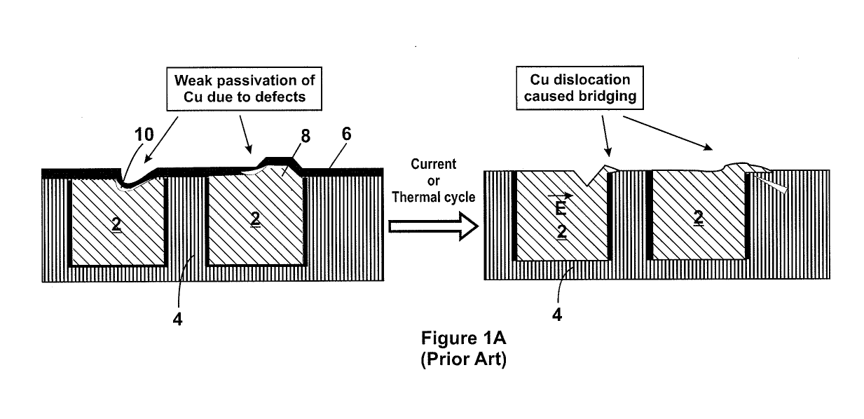

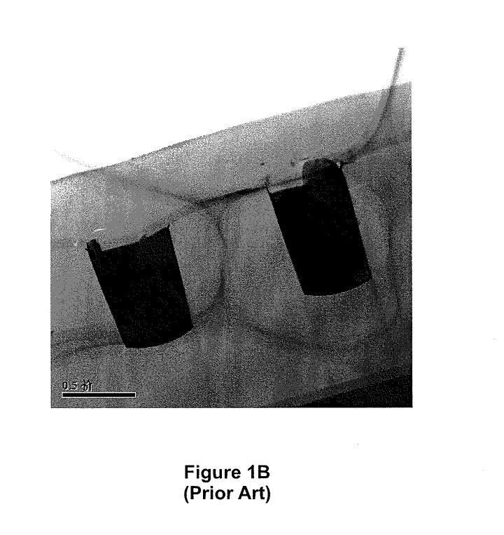

In a second possible operational mode, test structure 300 may be employed to test for extrusion of Cu. Specifically, as shown above in connection with FIGS. 1A-B, copper metal of the interconnect metallization lines may experience migration in response to application of a thermal energy or an applied bias. Such migration may result in the unwanted extrusion of a copper metallization line, such that it comes into electrical contact with an adjacent metallization line.

Accordingly, the test structure 300 of FIG. 3 may be utilized to identify such an extrusion as follows. First, a force voltage is applied to a force node (F3, F4, or F5) of one of the outer metallization lines (304 or 306). At the same time, voltage on the adjacent inner metallization line 308 is detected through sense node (S1 or S2). Detection of more than just a transient sense voltage in the adjacent line of metallization 308 reveals the existence of an electrically conducting extrusion or bridge between the lines.

In a third possible operational mode, test structure 300 may be employed to test for absolute breakdown voltage (V_{bd}) and/or time dependent dielectric breakdown (TDDB) characteristics of the interconnect structure. Specifically, breakdown voltage of dielectric material present between adjacent interconnect metallization lines is typically determined by applying a force voltage across the test structure, and sensing a sudden change in voltage revealing the unwanted flow of current through the dielectric, indicating a breakdown event. Because breakdown voltage is temperature dependent, conventionally this testing is performed while heating the test structure to over 100° C. in a furnace. Such testing, however, is relatively clumsy, as it requires relocation of the substrate into the furnace, together with establishing electrical connection with the substrate while disposed in the furnace.

Utilizing an embodiment of a test structure in accordance with the present invention, however, V_{bd} and TDDB may be detected without the need for placing the substrate within a furnace. Specifically, a bias may be applied to the polysilicon heater 310 of the test structure 300, in order to heat the polysilicon and the overlying interconnect structure.

While the interconnect is being heated, a force bias may be applied to node F4 of metallization portion 304, while a sense voltage is detected at sense node S5 of metallization portion 304. A surge in current characteristic of a breakdown in the dielectric layer, can be detected by the accompanying change in sense voltage. Alternatively, the force voltage can be applied from the other end of the metallization line at force node F5, with voltage sensed at node S4.

Still another possible operational mode for the test structure 300 in accordance with the embodiment of the present invention shown in FIG. 3, is to detect mobile ion contamination in the interconnect structure. Small positive ions such as sodium and potassium are common, but their presence in the interconnect structure can disrupt its conducting characteristics, resulting in possible failure of the device. Accordingly, modern semiconductor processing techniques go to great lengths to exclude such mobile ions from the devices being fabricated.

Such mobile ion exclusion is sometimes unsuccessful, however, and interconnect structures must accordingly be tested for the presence of such mobile ions.

One important test for the presence of mobile ions is the triangular voltage sweeping (TVS) technique. Specifically, TVS involves heating the interconnect structure, typically to a temperature of between about 250-275° C. Then, a positive bias is applied to the interconnect, and a current-voltage sweep from positive to negative bias is performed. The measured current voltage (CV) curve is compared with the capacitance exhibited by the dielectric component of the interconnect, and then integrated over the applied bias. One specification describing the TVS technique are the JEDEC Foundry Process Qualification Guidelines JP001.01, which are incorporated by reference herein for all purposes. In particular, JEDEC guideline JP001.01, §11.2 states in pertinent part:

### 11.2.1 Triangular Voltage Sweep (TVS) Test Requirements

| | |
|---|---|
| Literature references | M. W. Hilen and J. F. Verwey, Chapter 8 of Instabilities in Silicon |
| | Devices, Vol. 1, edited by G. Barbottin and A. Vapaille, 1986 |
| | E. H. Nicolian and J. R. Brews, MOS Physics and Technology, 1982 |
| Test parameters | Mobile ion concentration from capacitor displacement current |
| Test structures | a) NMOS and PMOS capacitor |
| | b) Metal-Insulator-Metal Capacitor |
| Method | At the temperature of >200° C. apply +1.0 MV/cm and hold for 90 |
| | sec (or shorter for T >200° C.). Ramp down from +1.0 MV/cm to −1.0 |
| | MV/cm with 0.01 MV/cm-sec ramp rate while measuring current |
| | through the capacitor. Hold at −1.0 MV/cm for 90 sec (or shorter for |
| | T >200° C.). Ramp up from −1.0 MV/cm to +1.0 MV/cm with 0.01 |
| | MV/cm-sec ramp rate while measuring current through the capacitor. |
| | Calculate mobile ion concentration from |
| | N₁ = (area under I_{CAP}-t curve)/[(capacitor area) × (electron charge)]. |
| Failure Criteria | Ionic concentration (Ni) level above foundry specified limit |
| Model to be used | None |
| Sample size | 3 lots, 1 wafer per lot, 2 capacitors per wafer |

Inclusion of the polysilicon heater element into the test structure in accordance with embodiments of the present invention, allows the TVS technique to also be conducted directly on the substrate, without the need for an external heating device. Specifically, a current voltage sweep of one or more of the lines of metallization in the test structure, heated by the polysilicon pad, may be employed to detect the presence of mobile ions such as sodium or potassium.

Still another possible use for the test structure 300 in accordance with an embodiment of the present invention of FIG. 3 is to detect effective k value of interlayer dielectric (ILD), and to measure drift in the k value of the interconnect structure over time. Specifically, both the absolute dielectric constant k, as well as a change or drift in k over time, of a dielectric material may be determined from the capacitance exhibited between two parallel conductors separated from each other by the dielectric material:

k=(d*C)/(∈₀*A); where:

k=dielectric constant;
d=distance of separation between parallel conductors;
C=capacitance;
A=area of the plates; and
∈₀=permittivity of free space.

For embodiments of test structures in accordance with the present invention, the quantities d, A, and ∈₀ are all known. A drift in the k value may thus be revealed by a changed capacitance C, which may be detected as a changed sense voltage received from a force voltage applied at a force node of the adjacent pair of metallization lines (either 304 and 308, or 308 and 306).

An absolute k value for the dielectric material of the interconnect structure may also be obtained from test structure 300 as follows. Specifically, a predetermined force bias may be applied to a first metallization line, and the resulting bias sensed on the adjacent metallization line. From the sense voltage measured, the capacitance of the test structure, and in turn the k value of the dielectric layer, can be determined.

While the invention has been described so far in connection with specific examples, it is understood that the present invention is not limited to these particular embodiments, and alternative embodiments are possible. For example, while the above description has focused upon using a test structure to evaluate characteristics of an interconnect structure fabricated from copper, the present invention is not limited to this particular embodiment. In accordance with alternative embodiments, a test structure could employ interconnect metallization comprising aluminum, rather than copper, and remain within the scope of the present invention. Rather than being fabricated utilizing damascene techniques, such an alternative embodiment of a test structure utilizing aluminum metallization could be formed by lithographic techniques.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A test structure comprising:
a polysilicon pad formed on a substrate;
a dielectric layer formed on the polysilicon pad; and
a metallization layer formed in a recess in the dielectric layer, the metallization layer comprising a first comb portion interdigitated with and electrically isolated from a second comb portion by the dielectric layer.

2. The test structure of claim 1 further comprising a first force node positioned at a first end of the first comb portion, a second force node positioned at a first end of the second comb portion, and a sense node positioned at an opposite end of the second comb portion.

3. The test structure of claim 1, wherein the metallization layer further comprises a serpentine portion positioned between the first comb portion and the second comb portion.

4. The test structure of claim 3 wherein the serpentine portion comprises a first sense node and a first force node positioned at a first end, and a second sense node and a second force node positioned at an opposite end.

5. The test structure of claim 1, wherein the metallization layer comprises copper.

6. The test structure of claim 1, wherein the metallization layer comprises aluminum.

7. A method of testing a semiconductor substrate comprising:
providing a test structure comprising a polysilicon pad formed on a substrate, a dielectric layer formed on the polysilicon pad, and a metallization layer formed in a recess in the dielectric layer, the metallization layer comprising a first comb portion interdigitated with a second comb portion and electrically isolated from the second comb portion by the dielectric layer; and
applying a force voltage at a force node of the first comb portion.

8. The method of claim 7 further comprising detecting a change in a sense voltage over time at a first end of the first comb portion opposite to a second end of the first comb portion to which the voltage was applied, the changed sense voltage indicating a change in resistance of the first comb portion attributable to electromigration of metal in the first comb portion.

9. The method of claim 7, wherein the voltage is maintained constant over time.

10. The method of claim 7 further comprising detecting a sense voltage at an end of the second comb portion, the sense voltage indicating extrusion of metal from the first comb portion.

11. The method of claim 7 further comprising applying a bias voltage to the polysilicon pad to increase a temperature of the first comb portion, and detecting a change in sense voltage over time in the first comb portion, the changed sense voltage indicating a breakdown of the dielectric layer.

12. The method of claim 11, wherein the bias voltage is increased over time.

13. The method of claim 7, wherein the force voltage is maintained constant over time.

14. The method of claim 7 further comprising applying a bias voltage to the polysilicon pad to increase a temperature of the first comb portion, and wherein the force voltage comprises a triangular voltage sweep to detect mobile ions in the first comb portion.

15. The method of claim 7 further comprising sensing a voltage in the second comb portion to indicate a dielectric k value for the dielectric layer.

16. The method of claim 15, wherein a change in the sense voltage over time indicates a drift in the dielectric layer k value.

17. The method of claim 7 further comprising applying a bias voltage to the polysilicon pad to heat the dielectric layer.

18. The method of claim 7, wherein interdigitated portions of the first and second comb portions are substantially parallel to one another, such that an absolute k value of the dielectric layer may be determined based upon a known distance between the interdigitated comb portions, a known area of the interdigitated comb portions, and a capacitance between the first and second comb portions calculated from the sense voltage.

19. The method of claim 7 further comprising a serpentine metal line interposed between the first and second comb portions, the serpentine having a sense node at each end.

20. The method of claim 19, wherein the detection of a sense voltage at the sense node of the serpentine metal line indicates a bridge between the serpentine and the first comb portion or the second comb portion when the voltage is applied to the first or second comb portion.
